(19) United States
(12) Patent Application Publication
(10) Pub. No.: US 2010/0178764 A1
(43) Pub. Date: Jul. 15, 2010

(54) METHOD FOR FABRICATING SEMICONDUCTOR DEVICE

(76) Inventors: Kenji NARITA, Osaka (JP); Yoshiharu Hidaka, Osaka (JP); Koji Utaka, Hyogo (JP); Takao Yamaguchi, Kyoto (JP); Itaru Kanno, Tokyo (JP); Hirokazu Kurisu, Tokyo (JP)

Correspondence Address: MCDERMOTT WILL & EMERY LLP, 600 13TH STREET, NW, WASHINGTON, DC, 20005-3096, US

(21) Appl. No.: 12/686,841

(22) Filed: Jan. 13, 2010

(30) Foreign Application Priority Data
Jan. 13, 2009 (JP) 2009-005025
Nov. 18, 2009 (JP) 2009-262581

(51) Int. Cl. H01L 21/3205

(52) U.S. Cl. 438/664; 257/E21.296

(57) ABSTRACT

A method for fabricating a semiconductor device, includes the steps of (a) forming a metal film containing a precious metal on a substrate having a semiconductor layer containing silicon or on a conductive film containing silicon formed on the substrate, (b) after step (a), heat-treating the substrate to allow the precious metal to react with silicon to form a silicide film containing the precious metal on the substrate or the conductive film, (c) after step (b), forming an oxide film on a portion of the silicide film underlying an unreacted portion of the precious metal using a first chemical solution, and (d) dissolving the unreacted portion of the precious metal using a second chemical solution.

### CROSS-REFERENCE TO RELATED APPLICATIONS

This application claims priority to Japanese Patent Applications No. 2009-005025 filed on Jan. 13, 2009 and No. 2009-262581 filed on Nov. 18, 2009, the disclosures of which including the specifications, the drawings, and the claims are hereby incorporated by reference in their entirety.

### BACKGROUND

The technology disclosed herein relates to methods for fabricating semiconductor devices, and more particularly, to a method for fabricating a semiconductor device including a step of removing a precious metal.

In Complementary Metal-Oxide-Semiconductor (CMOS) microfabrication processes, there has been a demand for devices having further higher performance and lower power consumption. Under such a circumstance, conventional CMOS processes have employed NiSi or CoSi having Ni or Co as a silicide material to further reduce silicide resistance.

In the microfabrication process, however, it is necessary to reduce silicide reaction of NiSi or CoSi to reduce the junction leakage current. Hence, an alloy of Ni or Co mixed with about 5 to 10% of Pt or Pd has been used as a silicide material. In particular, when an alloy of Ni and Pt (NiPt) is used as a silicide material, it can be expected to improve the heat resistance and reduce the junction leakage current.

In the silicidation process, in which an alloy film is formed on a Si substrate and is then subjected to thermal oxidation to allow the alloy to react with Si to form a silicide, it is necessary to remove unreacted alloy residues. Here, for example, when an alloy of Ni and Pt (NiPt) is used as a silicide material, a highly oxidative acid such as a mixture of sulfuric acid and hydrogen peroxide is used to remove unreacted NiPt after silicide formation (see Japanese Laid-Open Patent Publication No. 2002-124487, for example).

FIGS. 8A and 8B are views showing a conventional silicide formation process. In a step shown in FIG. 8A, after preparation of a semiconductor substrate 101 made of silicon, a top surface of which is partially exposed as a silicide formation region, an insulating film 102 is formed on the semiconductor substrate 101 excluding the silicide formation region. Next, NiPt 103 as a silicide material is deposited on an entire surface of the resultant semiconductor substrate 101. Thereafter, thermal oxidation is performed to form a silicide layer 110 made of a mixed crystal of NiSi and NiPtSi in the silicide formation region. Note that the mixed crystal of NiSi and NiPtSi is collectively referred to hereinafter as NiPtSi.

Next, in a step shown in FIG. 8B, unreacted NiPt 103 is removed, leaving only NiPtSi. In this step, the unreacted NiPt 103 is removed using a mixture 105 of sulfuric acid and hydrogen peroxide.

When a highly oxidative acid like the mixture of sulfuric acid and hydrogen peroxide is used to remove the unreacted NiPt 103 in the silicide formation process, Ni can be dissolved, but Pt, which has a low chemical reactivity, fails to dissolve and remains on the semiconductor substrate. Hence, in order to prevent Pt from remaining, aqua regia (solution containing nitric acid and hydrochloric acid) having oxidative power stronger than that of the mixture 105 may be used in place of the mixture 105 (see Japanese Laid-Open Patent Publication No. 2008-118088, for example).

### SUMMARY

However, in the conventional art, when aqua regia having strong oxidative power is used to dissolve and remove Pt residues, it also allows the dissolution reaction to proceed in the silicided NiPtSi portion because hydrochloric acid in the aqua regia is also highly corrosive to NiSi, and this may induce resistance anomaly or the like of the silicide layer. This phenomenon occurs for the following reason. An oxide film which is formed on NiSi during removal of unreacted Ni using a chemical solution such as a mixture of sulfuric acid and hydrogen peroxide, fails to be formed immediately below Pt residues since the Pt residues block formation of the oxide film. Therefore, during removal of the Pt residues using aqua regia, NiSi below the Pt residues are etched away together with the Pt residues. As a result, the surface of the silicide film is roughened.

According to illustrative embodiments of the present disclosure, the corrosion of the surface of the silicide film by a chemical solution such as aqua regia is reduced, and therefore, a good Pt-containing silicide film can be formed.

To achieve the aforementioned problems, a method for fabricating a semiconductor device according to an example of the present disclosure, includes the steps of (a) forming a metal film containing a precious metal on a substrate having a semiconductor layer containing silicon or on a conductive film containing silicon formed on the substrate, (b) after step (a), heat-treating the substrate to allow the precious metal to react with silicon to form a silicide film containing the precious metal on the substrate or the conductive film, (c) after step (b), forming an oxide film on a portion of the silicide film underlying an unreacted portion of the precious metal using a first chemical solution, and (d) dissolving the unreacted portion of the precious metal using a second chemical solution.

According to this method, the oxide film can also be formed on a portion underlying the precious metal in step (c), whereby the corrosion of the silicide layer can be reduced while removing an unnecessary portion of the precious metal in step (d).

The precious metal is preferably platinum, and the first chemical solution is preferably an aqueous solution containing a first oxidant. In step (c), dissolution of the unreacted portion of the precious metal preferably proceeds substantially simultaneously with formation of the oxide film.

The first chemical solution may be one solution selected from nitric acid, ozone water, hydrogen peroxide water, an aqueous potassium permanganate solution, an aqueous potassium chlorate solution, and an aqueous osmium tetroxide solution.

The first chemical solution may further contain a hydrochloric acid-based solution.

The first chemical solution may be one solution selected from a solution of hydrochloric acid to which potassium permanganate is added, a mixture of hydrochloric acid and hydrogen peroxide water, a mixture of hydrochloric acid and ozone water, a solution of hydrochloric acid to which chromium trioxide is added, a solution of hydrochloric acid to which potassium chlorate is added, and a solution of hydrochloric acid to which osmium tetroxide is added.

Step (c) may include immersing the substrate in the first chemical solution.

The second chemical solution may be a mixture of hydrochloric acid and nitric acid.

The method may further includes the step of (e) after step (b) and before step (c), dissolving an unreacted portion of the metal film using a mixture of a sulfuric acid-based solution and a second oxidant.

The mixture of the sulfuric acid-based solution and the second oxidant may be a mixture of sulfuric acid and hydrogen peroxide water, a mixture of sulfuric acid and ozone water, or a sulfuric acid electrolyte solution.

As described above, according to the semiconductor device fabricating method of the example of the present disclosure, the oxide film resistant to the treatment with the second chemical solution, such as aqua regia or the like, is also formed at an interface between precious metal residues and the silicide layer to which the precious metal residues are attached, before removal of the precious metal residues with the second chemical solution. Therefore, the corrosion of the silicide film by the second chemical solution which can dissolve the precious metal can be reduced. As a result, a good Pt-containing silicide film can be formed.

### BRIEF DESCRIPTION OF THE DRAWINGS

FIGS. 1A and 1B are cross-sectional views showing a method for fabricating a semiconductor device according to Embodiment 1 of the present disclosure.

FIGS. 2A and 2B are cross-sectional views showing the semiconductor device fabricating method of Embodiment 1.

FIG. 3 is a view showing a SEM image of a top surface of a semiconductor substrate after being treated with SPM.

FIG. 4 is a cross-sectional view schematically showing the top surface of the semiconductor substrate after being treated with SPM.

FIG. 5 is a view showing a SEM image of a top surface of a NiPtSi film observed when treated by a conventional method.

FIG. 6 is a cross-sectional view schematically showing a semiconductor substrate observed when treated by the method of Embodiment 1.

FIG. 7 is a view showing a SEM image of a top surface of a NiPtSi film observed when treated by the method of Embodiment 1.

FIGS. 8A and 8B are schematic views showing a conventional silicide formation process.

FIGS. 9A and 9B are cross-sectional views showing a method for fabricating a semiconductor substrate according to Embodiment 3 of the present disclosure.

FIGS. 10A and 10B are cross-sectional views showing the semiconductor device fabricating method of Embodiment 3.

### DETAILED DESCRIPTION

### Embodiment 1

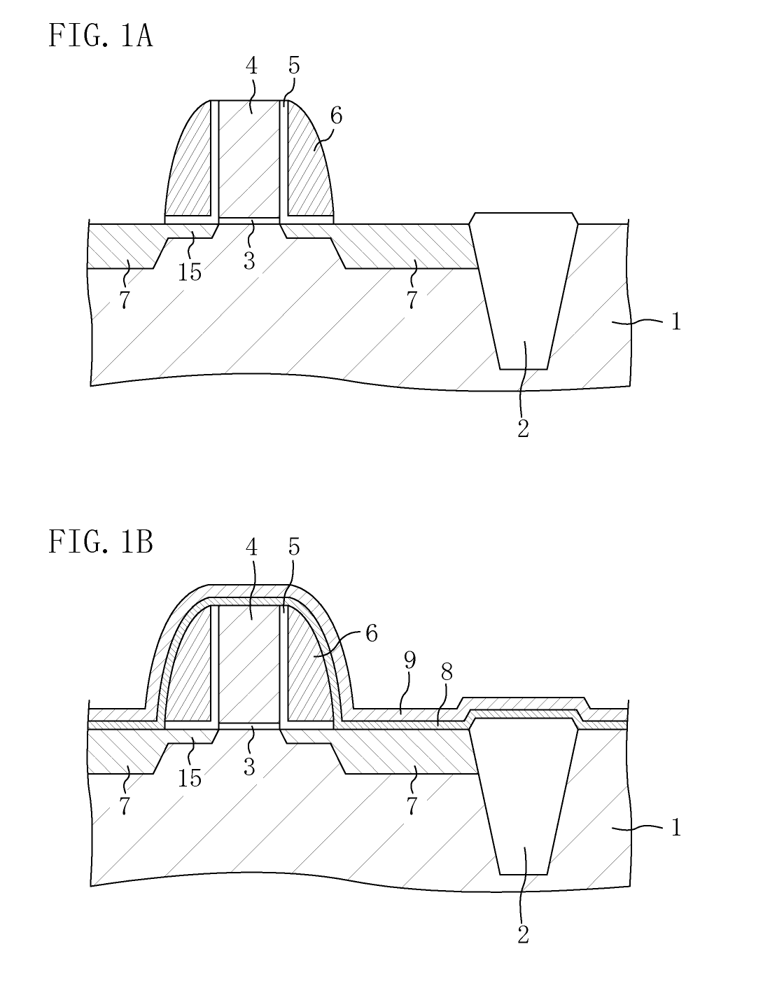

An example of a method and apparatus for fabricating a semiconductor device according to Embodiment 1 of the present disclosure will be described hereinafter with reference to FIGS. 1A-7.

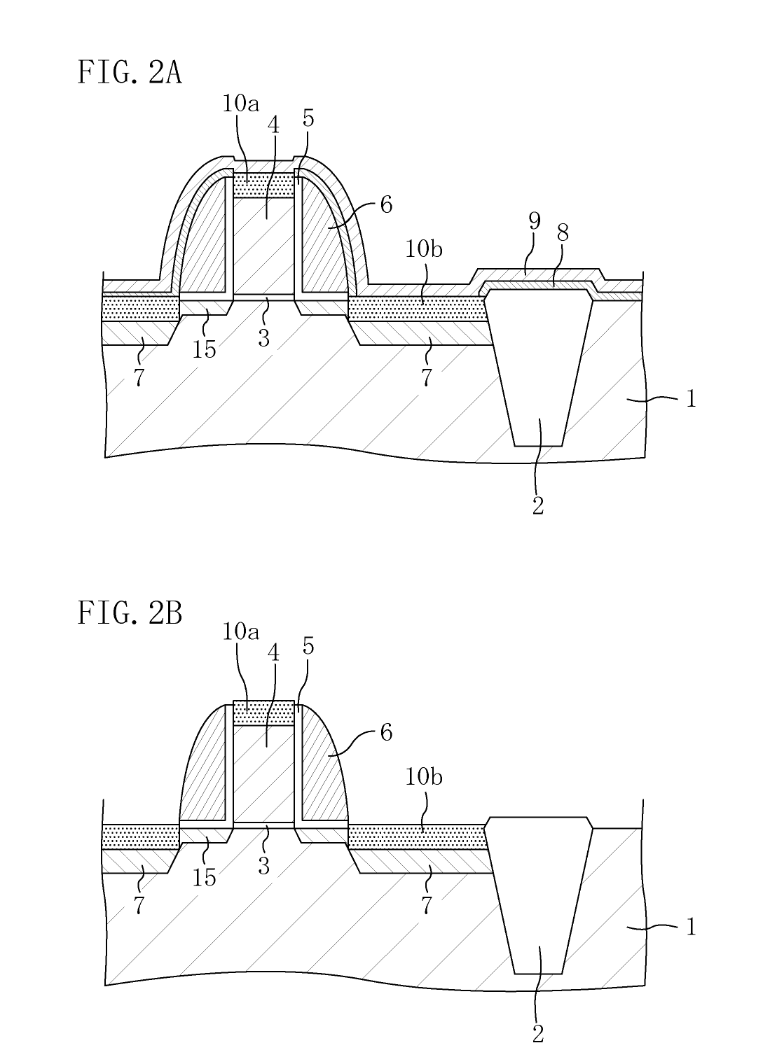

FIGS. 1A, 1B, 2A and 2B are cross-sectional views showing the semiconductor device fabricating method of Embodiment 1 of the present disclosure.

Initially, in a step shown in FIG. 1A, isolation regions 2 are formed in a semiconductor substrate 1 made of silicon by shallow trench isolation (STI) or the like. Next, a gate insulating film 3 made of a silicon oxide film having a thickness of 2 nm is formed on the semiconductor substrate 1 between each isolation region 2 by thermal oxidation. Next, a polysilicon film having a thickness of 100 nm is formed on an entire surface of the semiconductor substrate 1 by chemical vapor deposition (CVD), and then a dopant impurity is introduced into the polysilicon film by ion implantation. Here, when an NMOS transistor is to be formed, phosphorus is implanted as an n-type dopant impurity at an accelerating voltage of 15 keV and a dose of 1×10¹⁶ cm⁻², for example. When a PMOS transistor is to be formed, boron is implanted as a p-type dopant impurity at an accelerating voltage of 5 keV and a dose of 5×10¹⁵ cm⁻², for example. Next, the polysilicon film is patterned by photolithography and dry etching, to form a gate electrode (conductive film) 4 made of the polysilicon film.

Next, using the gate electrode 4 as a mask, a dopant impurity is introduced into regions of the semiconductor substrate 1 located on opposite sides of the gate electrode 4 by ion implantation. Here, when an NMOS transistor is to be formed, arsenic is implanted as an n-type dopant impurity at an accelerating voltage of 2 keV and a dose of 1×10¹⁵ cm⁻², for example. When a PMOS transistor is to be formed, boron is implanted as a p-type dopant impurity at an accelerating voltage of 0.5 keV and a dose of 3×10¹⁵ cm⁻², for example. As a result, shallow impurity diffusion regions are formed which are to be extension regions 15 of source/drain diffusion layers.

Next, a silicon oxide film having a thickness of 10 nm and a silicon nitride film having a thickness of 50 nm are formed on an entire surface of the semiconductor substrate 1 by CVD. Next, the silicon oxide film and the silicon nitride film are anisotropically etched by reactive ion etching (RIE) to form sidewall insulating films 5 made of the silicon oxide film and sidewall insulating films 6 made of the silicon nitride film on sidewall portions of the gate electrode 4. Next, using the gate electrode 4 and the sidewall insulating films 5 and 6 as a mask, a dopant impurity is introduced into regions of the semiconductor substrate 1 located on opposite sides of the gate electrode 4 and the sidewall insulating films 5 and 6 by ion implantation. Here, when an NMOS transistor is to be formed, arsenic is implanted as an n-type dopant impurity at an accelerating voltage of 20 keV and a dose of 5×10¹⁵ cm⁻², for example. When a PMOS transistor is to be formed, boron is implanted as a p-type dopant impurity at an accelerating voltage of 5 keV and a dose of 5×10¹⁵ cm⁻², for example. As a result, deep impurity diffusion regions of the source/drain diffusion layers are formed. Next, the dopant impurity introduced in the impurity diffusion regions is activated by a predetermined thermal treatment, thereby forming source/drain diffusion layers 7.

Next, in a step shown in FIG. 1B, for example, a NiPt film 8 having a thickness of 7 to 15 nm is formed as a metal film on an entire surface of the semiconductor substrate 1 by sputtering using, for example, a nickel (Ni) target to which platinum (Pt) is added. The percentage of Pt in the composition of the target is 2 to 10 atom %, for example. Next, for example, a protection film 9 made of a TiN film having a thickness of 5 to 30 nm is formed on the NiPt film 8 by, for example, sputtering. The protection film 9 is provided to prevent oxidation of the NiPt film 8.

Next, in a step shown in FIG. 2A, for example, rapid thermal annealing (RTA) is performed as a thermal treatment for silicidation. For example, the thermal treatment is performed at 200 to 400° C. for 30 sec. This allows NiPt of the NiPt film 8 and Si in a top portion of the gate electrode 4 to react with each other to form a NiPtSi film 10a on the gate electrode 4, and also allows NiPt of the NiPt film 8 and Si in top portions of the source/drain diffusion layers 7 to react with each other to form NiPtSi films 10b on the source/drain diffusion layers 7.

Next, in a step shown in FIG. 2B, unreacted portions of the protection film 9 and the NiPt film 8 are selectively removed by wet etching using a comparatively high-temperature chemical solution containing an oxidant.

Here, for example, a sulfuric acid-hydrogen peroxide mixture (SPM) solution is used as the oxidant-containing chemical solution. Note that the concentrations (percentages by volume) of sulfuric acid and hydrogen peroxide in the SPM solution are 50 to 90 vol % and 10 to 50 vol %, respectively, for example.

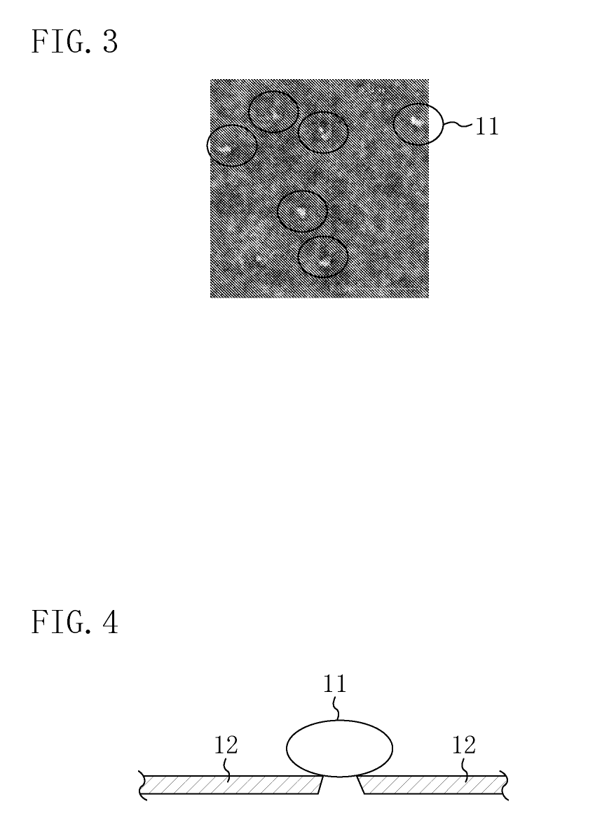

When the SPM solution is used, the protection film 9 made of a TiN film and Ni in the NiPt film 8 can be dissolved, while Pt cannot be dissolved, as shown in FIGS. 3 and 4. Hence, Pt particles 11 remain on the semiconductor substrate 1, the isolation region 2 and the gate electrode 4. FIG. 3 shows a SEM image of a top surface of the semiconductor substrate. It can be seen from FIG. 3 that the Pt particles 11 remain on the NiPtSi films 10a and 10b.

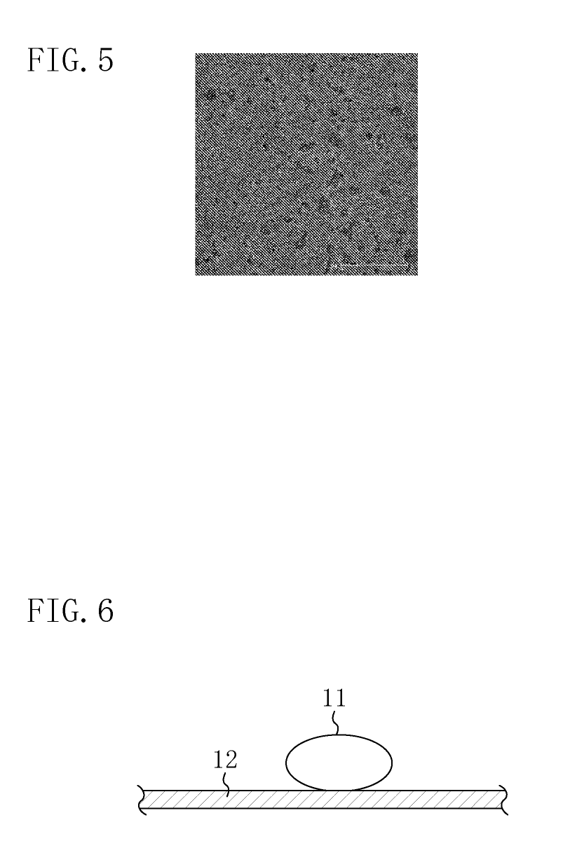

Next, the semiconductor substrate 1 is immersed in a chemical solution containing chlorine and an oxidant to intentionally oxidize top surfaces of the NiPtSi films 10a and 10b. This treatment allows formation of a silicon oxide film 12 on the NiPtSi films 10a and 10b in regions below the Pt particles 11 as well as in the other regions, while gradually dissolving Pt. Specifically, by immersing the semiconductor substrate 1 in a solution of hydrochloric acid to which potassium permanganate is added (KMnO₄: 1 to 7 wt %, treatment temperature: 40° C. to 70° C.) for five minutes, a uniform silicon oxide film 12 having a thickness of about 1 to 2 nm can be formed in entire top surfaces of the NiPtSi films 10a and 10b including regions below the Pt particles 11 attached thereto, as shown in FIG. 6. This step is preferably performed by single wafer processing, or alternatively, may be performed by batch processing in which a plurality of wafers are simultaneously processed.

Finally, the remaining Pt particles 11 are thoroughly dissolved using a strong acid, such as aqua regia (nitric acid:hydrochloric acid=1:3 by volume). Chlorine in aqua regia is also corrosive to Ni and Pt in the NiPtSi films 10a and 10b, turning Ni and Pt to their chloride ions, and therefore, the NiPtSi films 10a and 10b are dissolved. Here, for example, 60 wt % nitric acid and 36 wt % hydrochloric acid are used in preparation of aqua regia.

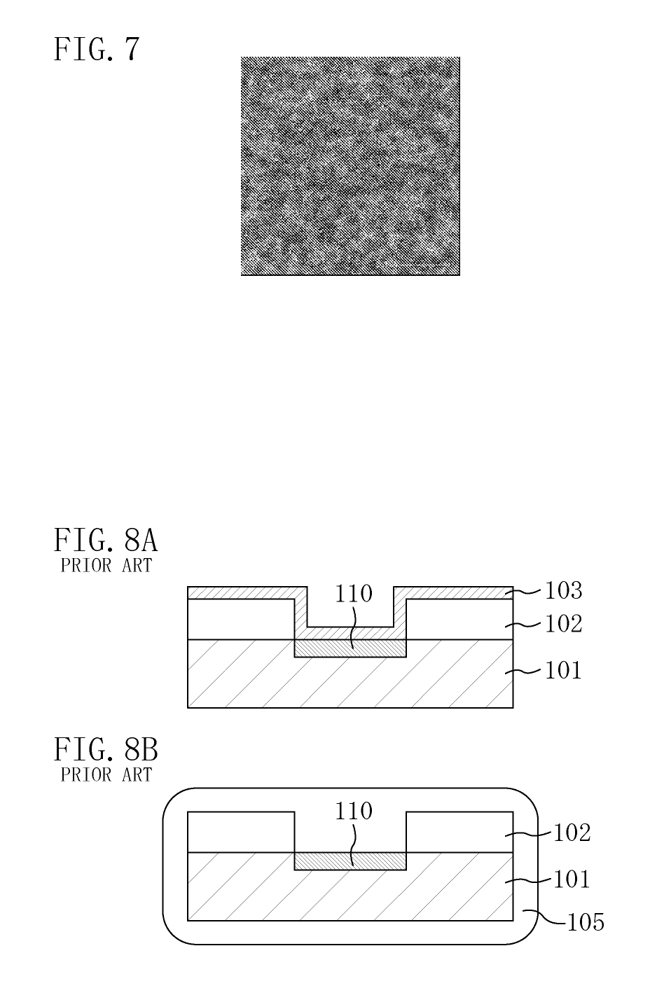

FIG. 7 is a view showing a SEM image of a top surface of a NiPtSi film which is observed when treated with SPM, followed by a treatment using the solution of hydrochloric acid to which potassium permanganate is added and then removal of Pt particles with aqua regia. In order to remove Pt particles, the NiPtSi film was treated with aqua regia for 120 sec.

It can be seen from FIG. 7 that, according to the method of this embodiment, portions of the NiPtSi film where the Pt particles 11 were present are also not dissolved, so that even and good NiPtSi films 10a and 10b are formed.

In FIG. 4 showing a NiPtSi surface state after the treatment with the SPM solution, while the silicon oxide film 12 is formed in exposed portions of the top surfaces of the NiPtSi films 10a and 10b because the SPM solution has oxidative power, the silicon oxide film 12 is not formed in the portions of the NiPtSi films 10a and 10b below the remaining Pt particles 11 attached thereto. The silicon oxide film 12 is not dissolved in aqua regia, as known in the art. Hence, when the Pt particles 11 are dissolved and removed with aqua regia in this state, the portions of the NiPtSi films 10a and 10b having the Pt particles 11 formed thereon are dissolved while the other portions thereof having no Pt particles are not be dissolved, as is seen from FIG. 5 showing a SEM image of the NiPtSi films 10a and 10b after the treatment with aqua regia. As a result, the resistance of the silicide layer formed may increase, or variations in characteristics of the transistor may be induced.

Therefore, in this example, following the treatment with the SPM solution, a protective oxide film is formed in an entire surface of the NiPtSi film using a chemical solution containing hydrochloric acid and an oxidant before the aforementioned aqua regia treatment is performed. As a result, the Pt particles 11 can be efficiently removed without dissolving the entirety of the NiPtSi films 10a and 10b.

Although SPM is used as a solution for removing unreacted NiPt in the method of this embodiment, the present disclosure is not limited to this. A sulfuric acid-based chemical solution to which an oxidant is added, such as a mixture of sulfuric acid and ozone water (H₂SO₄:O₃=1 to 5:1, 80° C. to 160° C.), a sulfuric acid electrolyte solution (80° C. to 100° C.), or the like, can be used to achieve a similar effect. Note that the mixture of sulfuric acid and ozone water specifically contains 98 wt % sulfuric acid and 20 ppm ozone water, for example.

Although a solution of hydrochloric acid to which potassium permanganate is added is used to gradually dissolve Pt particles while oxidizing the top surfaces of the NiPtSi films 10a and 10b in this embodiment, any other chemical solutions containing chlorine and an oxidant can be used. For example, a similar effect can be obtained using the following solutions: a mixture of hydrochloric acid (concentration: 36 wt %) and hydrogen peroxide water (concentration: 31 wt %) (HCl:H₂O₂=3 to 5:1; treatment temperature: 40° C. to 70° C.), a mixture of hydrochloric acid (concentration: 36 wt %) and ozone water (concentration: 20 ppm) (HCl:O₃=3 to 5:1; treatment temperature: 40° C. to 70° C.), a solution of hydrochloric acid to which potassium permanganate is added (KMnO₄: 1 to 7 wt %; treatment temperature: 40° C. to 70° C.), a solution of hydrochloric acid to which chromium trioxide is added (CrO₃: 1 to 5 wt %; treatment temperature: 40° C. to 70° C.), a solution of hydrochloric acid to which potassium chlorate is added (KClO₃: 1 to 7 wt %; treatment temperature: 40° C. to 70° C.), a solution of hydrochloric acid to which osmium tetroxide is added (OsO₄: 1 to 6 wt %; treatment temperature: 40° C. to 70° C.), and dilute solutions of the aforementioned solutions diluted one- to seven-fold with water.

Although aqua regia (nitric acid:hydrochloric acid=1:3 by volume) is used as a solution for removing remaining Pt particles and the removal treatment is performed for 120 sec in this embodiment, the present disclosure is not limited to this. A similar effect can be obtained under other conditions (nitric acid:hydrochloric acid:water=1:2 to 7:0 to 5, treatment temperature: 40° C. to 60° C., treatment time: 25 sec to 180 sec).

As described above, according to the semiconductor device fabricating method of this embodiment, after the SPM treatment the NiPtSi film is treated with a solution which has both an ability to oxidize the surface of the NiPtSi film and an ability to dissolve Pt particles remaining on the surface of the NiPtSi film, whereby the uniform silicon oxide film 12 having a thickness of about 1 to 2 nm can be intentionally formed in the surfaces of the NiPtSi films 10a and 10b. Therefore, when Pt particles are dissolved with aqua regia, the dissolution and corrosion of the NiPtSi films 10a and 10b can be reduced. As a result, the corrosion of the silicide surface by aqua regia having Pt dissolving power is reduced, whereby a good platinum-containing silicide film can be formed.

Moreover, in the semiconductor device of the embodiment described above, an SOI substrate having a silicon-containing semiconductor layer or the like may be used in place of the semiconductor substrate.

Moreover, in the method of this embodiment, the NiPtSi film may be treated with a solution which has both an ability to oxidize the surface of the NiPtSi film and an ability to dissolve Pt particles remaining on the surface of the NiPtSi film without a treatment with SPM, and thereafter, Pt may be removed using aqua regia or the like. Also in this case, the NiPtSi film can be protected during removal of Pt.

### Second Embodiment

A method for fabricating a semiconductor device according to a second embodiment of the present disclosure will be described hereinafter. The method of this embodiment is different from that of the first embodiment in that nitric acid having a temperature of 70° C. is used as the comparatively high-temperature chemical solution containing an oxidant after the SPM treatment.

Moreover, the fabrication method of this embodiment is similar to that of the first embodiment until the step of forming the NiPtSi films 10a and 10b and selectively removing unreacted metal from the protective film 9 and the NiPt film 8 using the SPM solution (at a middle point in the step of FIG. 2B).

After the unreacted metal is removed using the SPM solution, the semiconductor substrate 1 is immersed in a chemical solution containing an oxidant. Here, for example, when nitric acid (2 wt %, 70° C.) is used as an example of the chemical solution containing an oxidant, the semiconductor substrate 1 is immersed in the nitric acid for 60 min. As a result, as shown in FIG. 6, a uniform silicon oxide film 12 having a thickness of about 1 to 2 nm can be formed in entire top surfaces of the NiPtSi films 10a and 10b including regions below the Pt particles 11 attached thereto. This step is preferably performed by batch processing in which a plurality of wafers are simultaneously treated, or alternatively, may be performed by single wafer processing. Moreover, although the immersion treatment is performed using 2 wt % nitric acid at 70° C. for 60 min in this example, a similar effect can be obtained if the nitric acid concentration is within the range of 0.5 wt % to 15 wt %, the treatment temperature is within the range of 40° C. to 75° C., and the treatment time is within the range of 15 min to 90 min. The treatment time may be reduced by increasing the nitric acid concentration or the treatment temperature.

Thereafter, by performing the aforementioned aqua regia treatment, the Pt particles 11 can be efficiently removed while avoiding dissolution of the entirety of the NiPtSi films 10a and 10b.

Although SPM is used as a solution for removing unreacted NiPt in the method of this embodiment, the present disclosure is not limited to this. A sulfuric acid-based chemical solution to which an oxidant is added, such as a mixture of sulfuric acid and ozone water (H₂SO₄:O₃=1 to 5:1, 80° C. to 160° C.), a sulfuric acid electrolyte solution (80° C. to 100° C.), or the like, can be used to achieve a similar effect. Note that the mixture of sulfuric acid and ozone water specifically contains 98 wt % sulfuric acid and 20 ppm ozone water, for example.

Although nitric acid is used as a solution for oxidizing the top surfaces of the NiPtSi films 10a and 10b in this embodiment, any aqueous solution containing an oxidant can be used. For example, an effect similar to that which is obtained when nitric acid is used can be obtained using an aqueous oxidant solution, such as ozone water (0.01 to 5 ppm, 20° C. to 30° C., 30 min to 90 min), hydrogen peroxide water (1 wt % to 30 wt %, 20° C. to 50° C., 30 min to 90 min), an aqueous potassium permanganate solution (0.5 wt % to 10 wt %, 40° C. to 70° C., 30 min to 90 min), an aqueous chromium trioxide solution (0.5 wt % to 10 wt %, 40° C. to 70° C., 30 min to 90 min), an aqueous potassium chlorate solution (0.5 wt % to 10 wt %, 40° C. to 70° C., 30 min to 90 min), an aqueous osmium tetroxide solution (0.5 wt % to 10 wt %, 40° C. to 70° C., 30 min to 90 min), or the like.

Moreover, if an aqueous solution which does not contain hydrochloric acid and contains only an oxidant is used, the number of lines for supplying the chemical solution can be reduced as compared to when a solution containing hydrochloric acid is used. Therefore, the chemical solution treatment can be performed using a simpler apparatus configuration, and therefore, the chemical solution can be more easily replenished and managed, whereby the cost of the chemical solution can be reduced and the load of treatment of liquid waste can be reduced.

Although aqua regia (nitric acid:hydrochloric acid=1:3 by volume, 60° C.) is used as a solution for removing remaining Pt particles and the removal treatment is performed for 120 sec in the method of this embodiment, the treatment conditions are not limited to these. For example, an effect similar to that which is obtained when aqua regia is used can be obtained using a chemical solution (nitric acid:hydrochloric acid:water=1:1 to 7:0 to 10 by volume) at a treatment temperature of 40° C. to 60° C. for a treatment time of 25 sec to 180 sec.

As described above, according to the semiconductor device fabricating method of this embodiment, a solution capable of oxidizing the surfaces of the NiPtSi films 10a and 10b is used after the SPM treatment, whereby the silicon oxide film 12 can be intentionally formed in the surfaces of the NiPtSi films 10a and 10b. Therefore, when Pt particles are dissolved with aqua regia, the dissolution and corrosion of the NiPtSi films 10a and 10b can be reduced. As a result, the corrosion of the silicide surface by aqua regia having Pt dissolving power is reduced, whereby a good platinum-containing silicide film can be formed.

Moreover, in the semiconductor device of the embodiment described above, an SOI substrate having a silicon-containing semiconductor layer or the like may be used in place of the semiconductor substrate.

### Third Embodiment

Moreover, a method for fabricating a semiconductor device according to a third embodiment of the present disclosure will be described in which the treatment with SPM is not performed and a solution treatment having an ability to oxidize the surface of the NiPtSi film is performed before Pt is removed using aqua regia or the like. Also in this case, the NiPtSi film can be protected while removing Pt as described below.

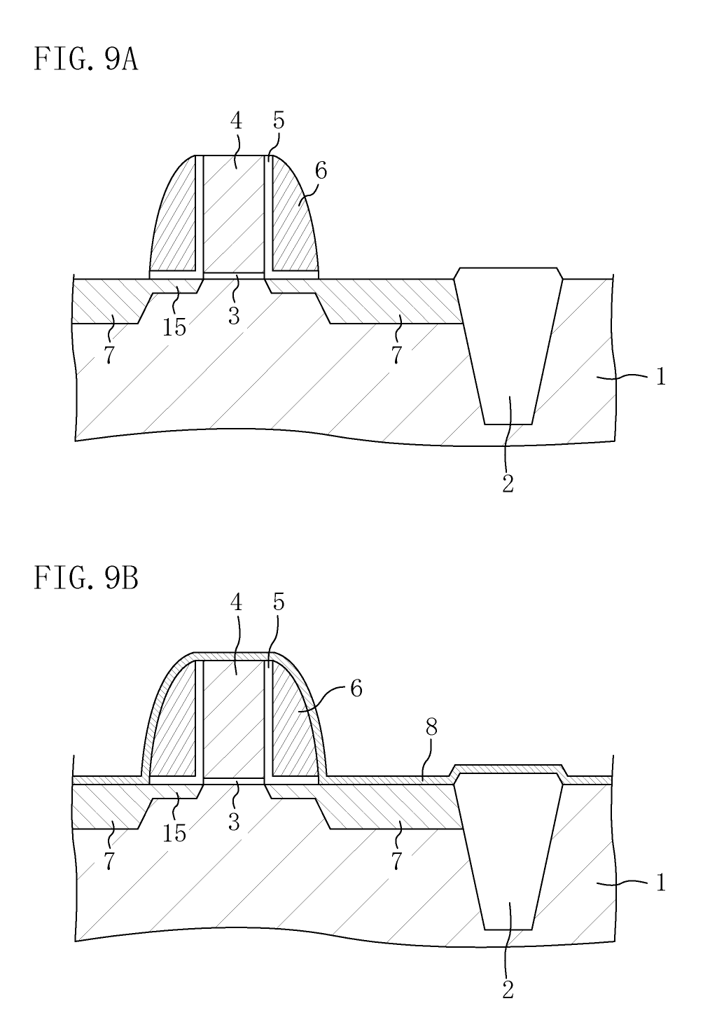

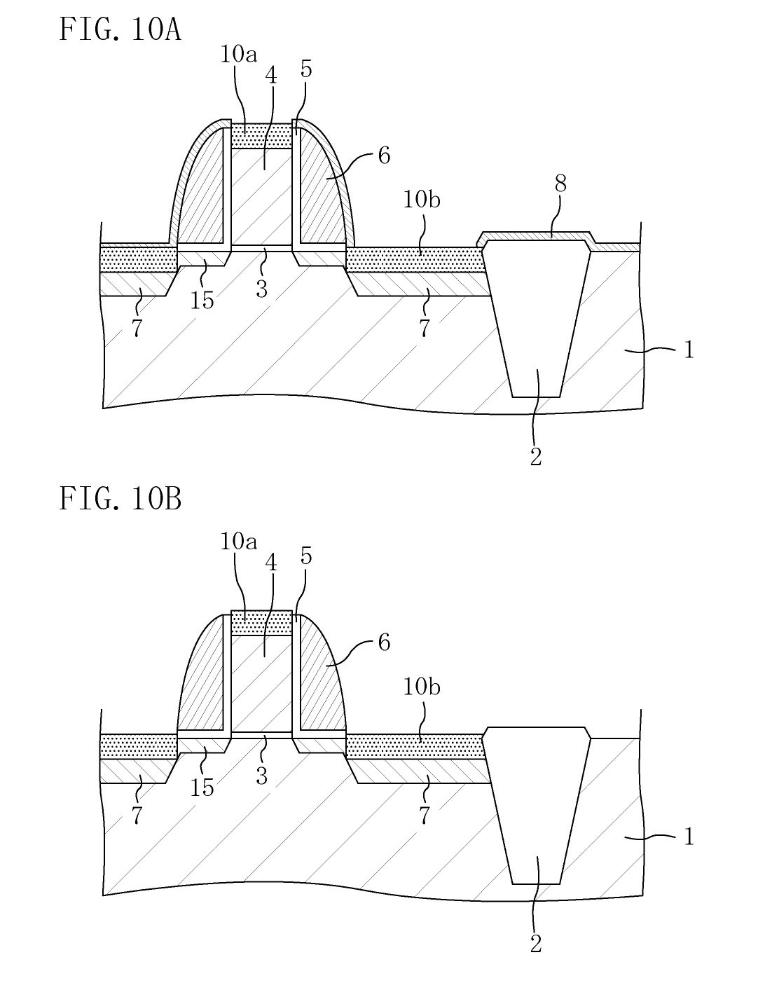

FIGS. 9A, 9B, 10A and 10B are cross-sectional views showing the semiconductor device fabricating method of the third embodiment of the present disclosure.

The fabrication method of this embodiment is similar to those of the first and second embodiments until the step of forming the source/drain diffusion layers 7 shown in FIG. 9A. Moreover, the fabrication method of this embodiment is different from that of the second embodiment in that the protective film 9 is not formed after formation of the source/drain diffusion layers 7 and the SPM treatment is not performed.

In a step shown in FIG. 9B, for example, a NiPt film 8 having a thickness of 7 to 25 nm is formed on an entire surface of the semiconductor substrate 1 by sputtering using, for example, a nickel (Ni) target to which platinum (Pt) is added. The percentage of Pt in the composition of the target is 2 to 10 atom %, for example.

Next, in a step shown in FIG. 10A, for example, RTA is performed as a thermal treatment for silicidation. The thermal treatment is performed at 200 to 400° C. for 20 sec, for example. This allows NiPt in the NiPt film 8 and Si in a top portion of the gate electrode 4 to react with each other to form a NiPtSi film 10a on the gate electrode 4, and also allows NiPt in the NiPt film 8 and Si in a top portion of the source/drain diffusion layer 7 to react with each other to form a NiPtSi film 10b on the source/drain diffusion layers 7.

Next, in a step shown in FIG. 10B, an unreacted portion of the NiPt film 8 is selectively removed by wet etching using a comparatively high-temperature chemical solution containing an oxidant.

Here, in this embodiment, the semiconductor substrate is immersed in a chemical solution containing an oxidant to intentionally oxidize top surfaces of the NiPtSi films 10a and 10b. By this treatment, a silicon oxide film 12 can be formed in regions below Pt particles as well as the other regions of the NiPtSi films 10a and 10b. Specifically, by immersing the semiconductor substrate in nitric acid (2 wt %, 70°) for 60 min, a uniform silicon oxide film 12 having a thickness of about 1 to 2 nm can be formed in entire surfaces of the NiPtSi films 10a and 10b including regions below the Pt particles 11 attached thereto, as shown in FIG. 6. This step is preferably performed by batch processing in which a plurality of wafers are simultaneously treated, or alternatively, may be performed by single wafer processing. Moreover, although the immersion treatment is performed using 2 wt % nitric acid at 70° C. for 60 min in this example, a similar effect can be obtained if the nitric acid concentration is within the range of 0.5 wt % to 15 wt %, the treatment temperature is within the range of 40° C. to 75° C., and the treatment time is within the range of 15 min to 90 min. The treatment time may be reduced by increasing the nitric acid concentration or the treatment temperature.

Thereafter, by performing an aqua regia treatment (nitric acid:hydrochloric acid= 1:3 by volume, 60° C.), the Pt particles 11 can be efficiently removed while avoiding dissolution of the entirety of the NiPtSi films 10a and 10b.

After the treatment using nitric acid and then removal of Pt particles using aqua regia, the top surface of the NiPtSi film is similar to that which is obtained when treated by the method of the first embodiment (see the SEM image of FIG. 7). Note that the aqua regia treatment for removing Pt particles is performed for 120 sec. According to the method of this embodiment, it is found that portions of the NiPtSi film where the Pt particles 11 were present are also not dissolved, so that even and good NiPtSi films 10a and 10b are formed.

Although nitric acid is used as a solution for oxidizing the top surfaces of the NiPtSi films 10a and 10b in this embodiment, any aqueous solution containing an oxidant can be used. For example, an effect similar to that which is obtained when nitric acid is used can be obtained, in place of nitric acid, using an aqueous oxidant solution, such as ozone water (0.01 to 5 ppm, 20° C. to 30° C., 30 min to 90 min), hydrogen peroxide water (1 wt % to 30 wt %, 20° C. to 50° C., 30 min to 90 min), an aqueous potassium permanganate solution (0.5 wt % to 10 wt %, 40° C. to 70° C., 30 min to 90 min), an aqueous chromium trioxide solution (0.5 wt % to 10 wt %, 40° C. to 70° C., 30 min to 90 min), an aqueous potassium chlorate solution (0.5 wt % to 10 wt %, 40° C. to 70° C., 30 min to 90 min), an aqueous osmium tetroxide solution (0.5 wt % to 10 wt %, 40° C. to 70° C., 30 min to 90 min), or the like.

Moreover, if an aqueous solution which does not contain hydrochloric acid and contains only an oxidant is used, the number of lines for supplying the chemical solution can be reduced as compared to when a solution containing hydrochloric acid is used. Therefore, the chemical solution treatment can be performed using a simpler apparatus configuration, and therefore, the chemical solution can be more easily replenished and managed, whereby the cost of the chemical solution can be reduced and the load of treatment of liquid waste can be reduced.

Although aqua regia (nitric acid:hydrochloric acid=1:3 by volume, 60° C.) is used as a solution for removing remaining Pt particles and the removal treatment is performed for 120 sec in the method of this embodiment, the present disclosure is not limited to this. A similar effect can be obtained under other conditions (nitric acid:hydrochloric acid:water=1:2 to 7:0 to 5, treatment temperature: 40° C. to 60° C., treatment time: 25 sec to 180 sec).

Moreover, according to the method of this embodiment, the step of forming the protective film 9 made of TiN or the like and the SPM treatment can be omitted. By using an aqueous solution containing only an oxidant, the number of lines for supplying the chemical solution can be reduced as compared to when a solution containing hydrochloric acid is used. Therefore, the apparatus configuration can be simplified, and therefore, the chemical solution can be more easily replenished and managed, whereby the cost of the chemical solution can be reduced and the load of treatment of liquid waste can be reduced.

As described above, according to the semiconductor device fabricating method of this embodiment, a solution having an ability to oxidize the surface of NiPtSi films is used, whereby the silicon oxide film 12 can be intentionally formed in the surfaces of the NiPtSi films 10a and 10b. Therefore, when Pt particles are dissolved with aqua regia, the dissolution and corrosion of the NiPtSi film can be reduced. As a result, the corrosion of the silicide surface by aqua regia having Pt dissolving power is reduced, whereby a good platinum-containing silicide film can be formed.

In the semiconductor device of the embodiment described above, an SOI substrate having a silicon-containing semiconductor layer or the like may be used in place of the semiconductor substrate.

As described above, the semiconductor device fabricating methods according to the examples of the present disclosure are useful as a method for fabricating a semiconductor device having a silicide film containing a precious metal, such as Pt or the like.

Given the variety of embodiments of the present disclosure just described, the above description and illustrations should not be taken as limiting the scope of the present disclosure defined by the claims.

While the disclosure has been particularly shown and described with reference to the preferred embodiments thereof, it will be understood by those skilled in the art that various changes in form and details may be made without departing from the spirit and scope of the disclosure. It is intended to cover various modifications and similar arrangements and procedures, and the scope of the appended claims therefore should be accorded the broadest interpretation so as to encompass all such modifications and similar arrangements and procedures.

What is claimed is:

1. A method for fabricating a semiconductor device, comprising the steps of:
(a) forming a metal film containing a precious metal on a substrate having a semiconductor layer containing silicon or on a conductive film containing silicon formed on the substrate;
(b) after step (a), heat-treating the substrate to allow the precious metal to react with silicon to form a silicide film containing the precious metal on the substrate or the conductive film;
(c) after step (b), forming an oxide film on a portion of the silicide film underlying an unreacted portion of the precious metal using a first chemical solution; and
(d) dissolving the unreacted portion of the precious metal using a second chemical solution.

2. The method of claim 1, wherein
the precious metal is platinum, and the first chemical solution is an aqueous solution containing a first oxidant, and
in step (c), dissolution of the unreacted portion of the precious metal proceeds substantially simultaneously with formation of the oxide film.

3. The method of claim 1, wherein
the first chemical solution is one solution selected from nitric acid, ozone water, hydrogen peroxide water, an aqueous potassium permanganate solution, an aqueous potassium chlorate solution, and an aqueous osmium tetroxide solution.

4. The method of claim 2, wherein
the first chemical solution further contains a hydrochloric acid-based solution.

5. The method of claim 4, wherein
the first chemical solution is one solution selected from a solution of hydrochloric acid to which potassium permanganate is added, a mixture of hydrochloric acid and hydrogen peroxide water, a mixture of hydrochloric acid and ozone water, a solution of hydrochloric acid to which chromium trioxide is added, a solution of hydrochloric acid to which potassium chlorate is added, and a solution of hydrochloric acid to which osmium tetroxide is added.

6. The method of claim 1, wherein
step (c) includes immersing the substrate in the first chemical solution.

7. The method of claim 1, wherein
the second chemical solution is a mixture of hydrochloric acid and nitric acid.

8. The method of claim 1, further comprising the step of:
(e) after step (b) and before step (c), dissolving an unreacted portion of the metal film using a mixture of a sulfuric acid-based solution and a second oxidant.

9. The method of claim 8, wherein
the mixture of the sulfuric acid-based solution and the second oxidant is a mixture of sulfuric acid and hydrogen peroxide water, a mixture of sulfuric acid and ozone water, or a sulfuric acid electrolyte solution.
